(19) United States
(12) Patent Application Publication
(10) Pub. No.: US 2014/0170512 A1
(43) Pub. Date: Jun. 19, 2014

(54) METHOD FOR MITIGATING RECOVERABLE VOLTAGE LOSS THROUGH HUMIDIFICATION CONTROL

(71) Applicant: GM GLOBAL TECHNOLOGY OPERATIONS LLC, Detroit, MI (US)

(72) Inventors: Daniel T. Folmsbee, Victor, NY (US); Gary M. Robb, Honeoye Falls, NY (US)

(73) Assignee: GM GLOBAL TECHNOLOGY OPERATIONS LLC, Detroit, MI (US)

(21) Appl. No.: 13/720,200

(22) Filed: Dec. 19, 2012

(51) Int. Cl. H01M 8/04; G01R 31/36

(52) U.S. Cl. CPC H01M 8/04126; G01R 31/3648
USPC 429/428; 324/426

(57) ABSTRACT

A system and method for recovering fuel cell stack voltage loss through humidification control. The method includes determining a rate of contamination addition to a surface of a fuel cell electrode in the fuel cell stack and determining a rate of contamination removal from the surface of the fuel cell electrode. The method compares the rate of contamination addition to the rate of the contamination removal to determine whether contaminant surface coverage of the electrode is increasing or decreasing and, if increasing, determines whether the amount of contamination of the electrode is above a predetermined value, where, if so, stack reconditioning through wet stack operation may be performed.

### BACKGROUND OF THE INVENTION

1. Field of the Invention

This invention relates generally to a system and method for recovering fuel cell stack voltage loss through stack humidification control and, more particularly, to a system and method for recovering fuel cell stack voltage loss through stack humidification control that includes employing models to calculate the rate of contamination added to the surface of electrodes in the fuel cells of the stack and the rate of contamination removal from the surface of the electrodes to determine the contamination coverage on the electrodes.

2. Discussion of the Related Art

Hydrogen is a very attractive fuel because it is clean and can be used to efficiently produce electricity in a fuel cell. A hydrogen fuel cell is an electro-chemical device that includes an anode and a cathode with an electrolyte therebetween. The anode receives hydrogen gas and the cathode receives oxygen or air. The hydrogen gas is dissociated at the anode catalyst to generate free protons and electrons. The protons pass through the electrolyte to the cathode. The protons react with the oxygen and the electrons at the cathode catalyst to generate water. The electrons from the anode cannot pass through the electrolyte, and thus are directed through a load to perform work before being sent to the cathode.

Proton exchange membrane fuel cells (PEMFC) are a popular fuel cell for vehicles. The PEMFC generally includes a solid polymer electrolyte proton conducting membrane, such as a perfluorosulfonic acid membrane. The anode and cathode typically, but not always, include finely divided catalytic particles, usually a highly active catalyst such as platinum (Pt) that is typically supported on carbon particles and mixed with an ionomer. The catalytic mixture is deposited on opposing sides of the membrane. The combination of the anode catalytic mixture, the cathode catalytic mixture and the membrane define a membrane electrode assembly (MEA). MEAs are relatively expensive to manufacture and require certain conditions for effective operation.

Several fuel cells are typically combined in a fuel cell stack to generate the desired power. For example, a typical fuel cell stack for a vehicle may have two hundred or more stacked fuel cells. The fuel cell stack receives a cathode input gas, typically a flow of air forced through the stack by a compressor. Not all of the oxygen is consumed by the stack and some of the air is output as a cathode exhaust gas that may include water as a stack by-product. The fuel cell stack also receives an anode hydrogen input gas that flows into the anode side of the stack.

A fuel cell stack includes a series of bipolar plates positioned between the several MEAs in the stack, where the bipolar plates and the MEAs are positioned between two end plates. The bipolar plates include an anode side and a cathode side for adjacent fuel cells in the stack. Anode gas flow fields are provided on the anode side of the bipolar plates that allow the anode reactant gas to flow to the respective MEA. Cathode gas flow fields are provided on the cathode side of the bipolar plates that allow the cathode reactant gas to flow to the respective MEA. One end plate includes anode gas flow channels, and the other end plate includes cathode gas flow channels. The bipolar plates and end plates are made of a conductive material, such as stainless steel or a conductive composite. The end plates conduct the electricity generated by the fuel cells out of the stack. The bipolar plates also include flow channels through which a cooling fluid flows.

The membrane within a fuel cell needs to have sufficient water content so that the ionic resistance across the membrane is low enough to effectively conduct protons. Membrane humidification may come from the stack water by-product or external humidification. The flow of reactants through the flow channels of the stack has a drying effect on the cell membranes, most noticeably at an inlet of the reactant flow. However, the accumulation of water droplets within the flow channels could prevent reactants from flowing therethrough, and may cause the cell to fail because of low reactant gas flow, thus affecting stack stability. The accumulation of water in the reactant gas flow channels, as well as within the gas diffusion layer (GDL), is particularly troublesome at low stack output loads.

Wet stack operation, that is, operation with a high amount of water content, is desirable for system humidification, performance and contaminant removal. However, there are various reasons to operate a fuel cell stack with a lower amount of humidification, also known as dry operation. For example, as mentioned, wet stack operation can lead to fuel cell stability problems due to water build up, and could also cause anode starvation, i.e., low hydrogen reactants, resulting in carbon corrosion. In addition, wet stack operation can be problematic in freeze conditions due to liquid water freezing at various locations in the fuel cell stack.

In a fuel cell system, there are a number of mechanisms that can cause permanent loss of stack voltage performance, such as loss of catalyst activity, catalyst support corrosion and pinhole formation in the cell membranes. However, there are other mechanisms that can cause stack voltage losses that are substantially reversible, such as the cell membranes drying out, catalyst oxide formation, and build-up of contaminants on both the anode and cathode side of the stack.

In order for a PEM fuel cell system to be commercially viable, there generally needs to be a limitation of the noble metal loading, i.e., platinum or platinum alloy catalyst, on the fuel cell electrodes to reduce the overall system cost. As a result, the total available electro-chemically active surface area of the catalyst may be limited or reduced, which renders the electrodes more susceptible to contamination. The source of the contamination can be from the anode and cathode reactant gas feed streams including humidification water, or generated within the fuel cells due to the degradation of the MEA, stack sealants and/or bipolar plates. One particular type of contaminant includes anions, which are negatively charged, such as chlorine or sulfates. The anions tend to adsorb onto the platinum catalyst surface of the electrode during normal fuel cell operation when the cathode potential is typically over 650 mV, thus blocking the active site for oxygen reduction reaction, which leads to cell voltage loss. Moreover, if proton conductivity is also highly dependent on a contaminate free platinum surface, such as nano-structured thin film (NSTF) type electrodes, additional losses are caused by the reduced proton conductivity.

U.S. patent application Ser. No. 12/580,912, filed Oct. 16, 2009, titled, Automated Procedure For Executing In-Situ Fuel Cell Stack Reconditioning, assigned to the assignee of this application and herein incorporated by reference, discloses a system and method for reconditioning a fuel cell stack that includes increasing the humidification level of the cathode side of the stack to hydrate the cell membranes and providing hydrogen to the anode side of the fuel cell stack at system shut-down, where the system monitors reconditioning event triggers, reconditioning thresholds and reconditioning system checks so that the reconditioning process can be provided during vehicle operation.

Generally, stack reconditioning of the type referred to above includes running the fuel cell stack with high relative humidity to remove contaminates from the stack to recover from stack degradation. However, reconditioning is an abnormal operation and exposes the stack to wet operations that may cause reliability issues if liquid water ends up in anode flow-fields and low anode flow rates are not able to purge them out. Thus, reconditioning should be performed only when absolutely necessary. Previous stack reconditioning triggers included performing the reconditioning by monitoring the number of vehicle trips or key cycles. If the number of trips exceeded a threshold, which is considered as a representation of time after which stack voltage has degraded, the reconditioning process is triggered. However, improvements in triggering the reconditioning process can be made so that the reconditioning is only performed when necessary to reduce the abnormal operation conditions.

### SUMMARY OF THE INVENTION

In accordance with the teachings of the present invention, a system and method are disclosed for recovering fuel cell stack voltage loss through humidification control. The method includes determining a rate of contamination addition to a surface of a fuel cell electrode in the fuel cell stack and determining a rate of contamination removal from the surface of the fuel cell electrode. The method compares the rate of contamination addition to the rate of the contamination removal to determine whether contaminant surface coverage of the electrode is increasing or decreasing and, if increasing, determines whether the amount of contamination of the electrode is above a predetermined value, where, if so, stack reconditioning through wet stack operation may be performed.

Additional features of the present invention will become apparent from the following description and appended claims, taken in conjunction with the accompanying drawings.

### BRIEF DESCRIPTION OF THE DRAWINGS

FIG. 1 is a simple illustration of a fuel cell system; and

FIG. 2 is a flow chart diagram showing a process for reconditioning a fuel cell stack to recover stack voltage loss through humidification control.

### DETAILED DESCRIPTION OF THE EMBODIMENTS

The following discussion of the embodiments of the invention directed to a system and method for recovering a reversible stack voltage loss through humidification control is merely exemplary in nature, and is in no way intended to limit the invention or its applications or uses.

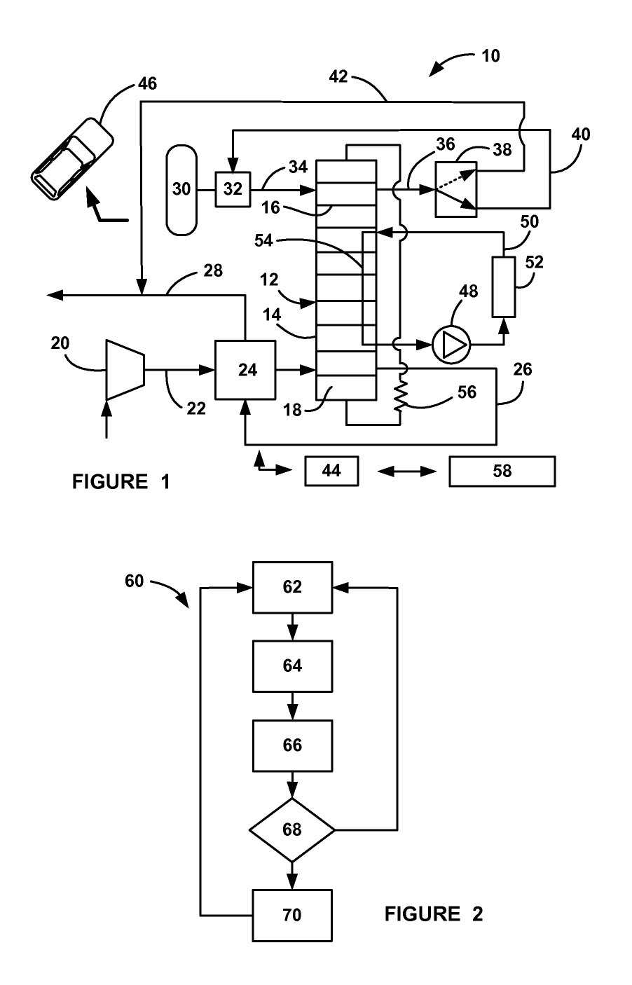

FIG. 1 is a simple block diagram of a fuel cell system 10 including a fuel cell stack 12 having a plurality of stacked fuel cells 14. The fuel cell system 10 would typically be provided on a vehicle 46 for the purposes of the invention as discussed below. As discussed above, the fuel cells in a typical fuel cell stack of this type will include MEAs having cell electrodes with the reactant catalyst and separated by bipolar plates having reactant flow channels and cooling fluid flow channels all in well known designs. Lines 16 represents the bipolar plates having the flow channels extending therethrough, where cell MEAs 18 including the cell diffusion media and electrodes including the catalyst would be between the bipolar plates 16.

A compressor 20 provides airflow to the cathode side of the fuel cell stack 12 on cathode input line 22 through a water vapor transfer (WVT) unit 24 that humidifies the cathode input air. The WVT unit 24 is employed in this embodiment as a non-limiting example, where other types of humidification devices may be applicable for humidifying the cathode inlet air, such as enthalpy wheels, evaporators, etc. In some fuel cell system designs, a by-pass line (not shown) may be provided around the WVT unit 24 to selectively control the humidity level provided to the cathode input reactant gas. A cathode exhaust gas is output from the stack 12 on a cathode exhaust gas line 26. The exhaust gas line 26 directs the cathode exhaust gas to the WVT unit 24 to provide the water content to humidify the cathode input air, where an output from the WVT unit 24 is provided on a system exhaust line 28 in this non-limiting system configuration.

The fuel cell system 10 also includes a source 30 of hydrogen fuel or gas, typically a high pressure tank, that provides hydrogen gas to an injector 32 that injects a controlled amount of the hydrogen gas to the anode side of the fuel cell stack 12 on an anode input line 34. Although not specifically shown, one skilled in the art would understand that various pressure regulators, control valves, shut-off valves, etc. would be provided to supply the high pressure hydrogen gas from the source 30 at a pressure suitable for the injector 32. The injector 32 can be any injector suitable for the purposes discussed herein. One example is an injector/ejector as described in U.S. Pat. No. 7,320,840, titled, Combination of Injector/Ejector for Fuel Cell Systems, issued Jan. 22, 2008, assigned to the assignee of this application and herein incorporated by reference.

An anode effluent gas is output from the anode side of the fuel cell stack 12 on an anode output line 36, which is provided to a bleed valve 38. As is well understood by those skilled in the art, nitrogen cross-over from the cathode side of the fuel cell stack 12 dilutes the hydrogen gas in the anode side of the stack 12, thereby affecting fuel cell stack performance. Therefore, it is necessary to periodically bleed the anode effluent gas from the anode sub-system to reduce the amount of nitrogen therein. When the system 10 is operating in a normal non-bleed mode, the bleed valve 38 is in a position where the anode effluent gas is provided to a recirculation line 40 that recirculates the anode gas to the injector 32 to operate it as an ejector and provide recirculated hydrogen gas back to the anode input of the stack 12. When a bleed is commanded to reduce the nitrogen in the anode side of the stack 12, the bleed valve 38 is positioned to direct the anode effluent gas to a by-pass line 42 that combines the anode effluent gas with the cathode exhaust gas on the line 28, where the hydrogen gas is diluted to be suitable for the environment. Although the system 10 is an anode recirculation system, the present invention will have application for other types of fuel cell systems including anode flow shift-systems, as would be well understood to those skilled in the art.

A pump 48 pumps a cooling fluid through the fuel cell stack 12 and a cooling fluid line 50 outside of the stack 12 and through a radiator 52. Line 54 within the fuel cell stack 12 is intended to represent the many flow channels provided in the stack 12, typically within the bipolar plates 16 in various designs, also well understood by those skilled in the art. A stack load 56 is shown electrically coupled to the fuel cell stack 12 and is intended to represent any electrical load on the fuel cell stack 12 consistent with the discussion herein.

Box 44 is intended to represent each and every sensor, circuit, device, etc. that provides data concerning the operation of the fuel cell system 10, including, but not limited to, RH sensors, temperature sensors, including ambient temperature, cooling fluid temperature, etc., high frequency resistance (HFR) circuits for determining stack water content, pressure sensors, voltage monitoring circuits for determining the voltage of each fuel cell in the stack 12, stack current density sensors, etc. A controller 58 receives inputs from each of these sensors, circuits and devices, and provides system control and calculations for the system 10 including the models discussed herein.

Controlling the operation of the fuel cell stack 12 so that liquid water is present at the fuel cell electrode surface is desirable for reducing contamination and thus recovering voltage loss. In other words, it is desirable to operate the fuel cell stack 12 so that the humidity level is above 100%, where liquid water would be present at the cell electrodes. It is believed that operating the cells with wet membranes reduces the stress on the membranes, which reduces the contaminants being released therefrom. This is typically accomplished by reducing the operating temperatures of the stack cooling fluid. However, it is not always possible or desirable for other reasons to operate the stack 12 at this humidity level. For example, during summer operation, higher ambient temperatures can make wet operation of the stack 12 more difficult. Additionally, during winter operation, vehicle cabin heating requirements can limit the minimum stack cooling fluid temperature. Also, it may not be desirable to operate the stack 12 at this level of humidity because the efficiency of operation of the stack 12 may be significantly reduced.

As the stack 12 ages, the desire to operate at the wet stack conditions to improve voltage performance more often is higher. Therefore, a comprehensive strategy for maintaining the presence of liquid water near the cell electrodes is desired. Various operating strategies can be performed to increase the likelihood of liquid water at the electrode surfaces. For times when wet operation is not possible, contaminants may build up on the cell electrodes and reduce stack performance through voltage loss. However, returning to wet operation has been shown to recover much of this loss. Therefore, managing the time between wet operation and acceptable predicted stack voltage loss can be optimized to maximize system efficiency.

The present invention proposes a process for recovering stack voltage loss through humidification control. Investigations have shown that contamination of the electrode surfaces in the MEAs 18 can be defined as contamination coverage on the surfaces where the amount of coverage of the contaminants is directly related to whether the catalyst under the contaminants is able to contribute to the cell reaction to generate power. From this, a desirable amount of contamination coverage on the electrode surface can be determined where if the contamination coverage exceeds that value, then loss of catalyst for the reaction is significant enough to affect the power output of the stack 12. As the amount of contamination coverage on the electrode surfaces increases, there is a direct correlation to the voltage loss of the stack 12.

The recovery process employs a contaminant surface coverage model for calculating the amount or coverage of contaminants on the cell electrodes. The coverage model uses two other models to determine the contamination coverage on the electrode, namely, a rate of contaminant addition to the electrode surface model that determines the rate that contaminants are being added to the electrode surface, and a rate of contaminant removal from the electrode surface model that determines the rate that contaminants are being removed from the electrode surface at any given point in time. As the surface coverage contamination increases, then the rate of addition of the contaminants is higher than the rate of the removal of the contaminants. The two rates will be equal once surface equilibrium is achieved.

If the surface contamination coverage is higher than a target coverage level, it will be desirable to increase the rate of contamination removal above the rate of addition of the contaminants until the target coverage is reached. This is accomplished by operating the system at higher humidification settings. The humidification settings can be a function of the difference between the actual surface coverage and the target surface coverage. Once the target surface coverage is achieved, the system 10 will return to nominal operating conditions.

The contaminant surface coverage model is an empirical model that is a function of the rate of contaminant addition to the electrode surface model and the rate of the contaminant removal from the electrode surface model. The contaminant surface coverage model compares relative rates of these models to determine if surface coverage is increasing or decreasing. The coverage model calculates the absolute level of surface coverage and compares it to a target surface coverage, and then calculates the conditions, i.e., humidification and time, required to decrease the surface coverage to the desired target level.

As mentioned above, electrode surface contamination is typically the result of breakdown of the membrane in the MEAs 18. The breakdown of the membranes is a function of the operating conditions. The rate of contaminant addition to the electrode surface model is also an empirical model and is a function of the local membrane temperature, the local membrane lambda, i.e., the amount of water held in the membrane, the local membrane theta, i.e., the diffusion media void fraction filled with liquid water, fuel cell inlet relative humidity, fuel cell outlet relative humidity, the age of the membrane, membrane damage previously experienced, and an estimated current surface coverage of the electrode from previous model estimations. Those skilled in the art would be able to provide a specific formula for weighting these values to determine the addition of the surface contaminants.

As the contaminants are being added to the surface of the electrodes in the MEAs 18, some of those contaminants are also being removed from the surface of the electrodes also based on the operating conditions of the fuel cell stack 12. The rate of contaminant removal from the surface model is also an empirical model that determines the removal of the contaminants from the electrode surface based on the operating conditions. The rate of contaminant removal from the surface model is a function of the local temperature of the membrane, the local membrane lambda, the local member theta, the amount of liquid water entering the fuel cell, the amount of liquid water leaving the fuel cell, the voltage history of the fuel cell, the fuel cell inlet relative humidity, the fuel cell outlet relative humidity and the estimated current surface coverage of the electrode from previous model estimations. The voltage history of the fuel cell is part of the rate of contaminant removal from the surface model because the ability of the electrode to hold contaminants decreases with cell voltage. Further, as discussed above, the liquid water flowing through the cell is what allows contaminants to be removed from the electrodes. Those skilled in the art would be able to provide a specific formula for weighting these values to determine the removal of the surface contaminants.

Thus, the contaminant surface coverage model uses the rate of contaminant addition to the surface model and the rate of contaminant removal from the surface model to determine the estimated amount of contamination coverage at any point of time considering the previous coverage, and whether the surface contamination is increasing or decreasing. If the estimated amount of contamination coverage is greater than some predetermined amount that is known to significantly affect stack performance, then the system may command a wet operation to reduce the amount of contamination if the other system parameters allow the wet operation.

FIG. 2 is a flow chart diagram 60 showing a process for recovering fuel cell stack voltage loss. For this process, the sensors, circuits and devices represented by the box 44 provides the necessary input data and the controller 58 performs the desired calculations. At box 62, the algorithm or control process within the system 10 determines the rate of contamination addition using the rate of contamination addition to the electrode surface model based on the discussion above. At box 64, the algorithm determines the rate of contaminant removal from the electrode surface using the rate of contamination removal from the electrode surface model as discussed above. At box 66, the algorithm then uses the surface coverage model to determine the contaminant surface coverage on the electrodes using the now determined rate of contamination addition and rate of contamination removal based on previous estimations of the surface coverage of the electrode. At decision diamond 68, the algorithm determines whether that surface coverage is above a predetermined value and, if so, action would be taken to reduce the contamination level, if possible, such as running the stack 12 at a higher humidification level at box 70.

As will be well understood by those skilled in the art, the several and various steps and processes discussed herein to describe the invention may be referring to operations performed by a computer, a processor or other electronic calculating device that manipulate and/or transform data using electrical phenomenon. Those computers and electronic devices may employ various volatile and/or non-volatile memories including non-transitory computer-readable medium with an executable program stored thereon including various code or executable instructions able to be performed by the computer or processor, where the memory and/or computer-readable medium may include all forms and types of memory and other computer-readable media.

The foregoing discussion disclosed and describes merely exemplary embodiments of the present invention. One skilled in the art will readily recognize from such discussion and from the accompanying drawings and claims that various changes, modifications and variations can be made therein without departing from the spirit and scope of the invention as defined in the following claims.

What is claimed is:

1. A method for recovering fuel cell stack voltage loss, said method comprising:
determining a rate of contamination addition to a surface of a fuel cell electrode in the fuel cell stack;
determining a rate of contamination removal from the surface of the fuel cell electrode in the fuel cell stack;
comparing the rate of contamination addition to the rate of the contamination removal to determine whether contaminant surface coverage of the electrode is increasing or decreasing; and
determining whether the amount of contamination of the electrode is above a predetermined value.

2. The method according to claim 1 wherein determining the rate of contamination addition to the surface of the electrode includes employing an empirical model.

3. The method according to claim 2 wherein the empirical model is a function of water content at the electrode and temperature of the fuel cell stack.

4. The method according to claim 3 wherein the empirical model is further a function of a local membrane lamda, fuel cell inlet relative humidity, fuel cell outlet relative humidity, membrane age, membrane damage previously experienced and an estimated current surface coverage of the surface of the electrode.

5. The method according to claim 1 wherein determining the rate of contaminant removal from the surface of the electrode includes employing an empirical model.

6. The method according to claim 5 wherein the empirical model is a function of liquid water present at the electrode and electrode voltage.

7. The method according to claim 6 wherein the empirical model is also a function of local membrane temperature, a local membrane lambda, a local diffusion media theta, liquid water entering the fuel cell, liquid water leaving the fuel cell, voltage history of the cell, fuel cell inlet relative humidity, fuel cell outlet relative humidity and an estimated current surface coverage of the surface of the electrode.

8. The method according to claim 1 further comprising operating the fuel cell stack at a higher relative humidity if it is determined that the surface coverage of contaminants on the electrode is above the predetermined value.

9. A method for recovering fuel cell stack voltage loss, said method comprising:
determining a rate of contamination addition to a surface of a fuel cell electrode in the fuel cell stack using a first empirical model;
determining a rate of contamination removal from the surface of the fuel cell electrode in the fuel cell stack using a second empirical model; and
comparing the rate of contamination addition to the rate of the contamination removal using a third empirical model to determine whether the amount of contamination of the electrode is above a predetermined value.

10. The method according to claim 9 further comprising operating the fuel cell stack at a higher relative humidity if it is determined that the surface coverage of contaminants on the electrode is above the predetermined value.

11. The method according to claim 9 wherein the first empirical model is a function of water content at the electrode, temperature of the fuel cell stack, a local membrane lamda, fuel cell inlet relative humidity, fuel cell outlet relative humidity, membrane age, membrane damage previously experienced and an estimated current surface coverage of the surface of the electrode.

12. The method according to claim 9 wherein the second empirical model is a function of liquid water present at the electrode, electrode voltage, local membrane temperature, a local membrane lambda, a local diffusion media theta, liquid water entering the fuel cell, liquid water leaving the fuel cell, voltage history of the cell, fuel cell inlet relative humidity, fuel cell outlet relative humidity and an estimated current surface coverage of the surface of the electrode.

13. A system for recovering fuel cell stack voltage loss, said system comprising:
means for determining a rate of contamination addition to a surface of a fuel cell electrode in the fuel cell stack;
means for determining a rate of contamination removal from the surface of the fuel cell electrode in the fuel cell stack; and
means for comparing the rate of contamination addition to the rate of the contamination removal to determine whether the amount of contamination of the electrode is above a predetermined value.

14. The system according to claim 13 further comprising means for operating the fuel cell stack at a higher relative humidity if it is determined that the surface coverage of contaminants on the electrode is above the predetermined value.

15. The system according to claim 14 wherein the means for determining the rate of contamination addition to the surface of the electrode employs an empirical model.

16. The system according to claim 15 wherein the empirical model is a function of water content at the electrode and temperature of the fuel cell stack.

17. The system according to claim 16 wherein the empirical model is further a function of a local membrane lamda, fuel cell inlet relative humidity, fuel cell outlet relative humidity, membrane age, membrane damage previously experienced and an estimated current surface coverage of the surface of the electrode.

18. The system according to claim 13 wherein the means for determining the rate of contaminant removal from the surface of the electrode employs an empirical model.

19. The system according to claim 18 wherein the empirical model is a function of liquid water present at the electrode and electrode voltage.

20. The system according to claim 19 wherein the empirical model is also a function of local membrane temperature, a local membrane lambda, a local diffusion media theta, liquid water entering the fuel cell, liquid water leaving the fuel cell, voltage history of the cell, fuel cell inlet relative humidity, fuel cell outlet relative humidity and an estimated current surface coverage of the surface of the electrode.
